(19) United States
(12) Patent Application Publication
(10) Pub. No.: US 2026/0322120 A1
(43) Pub. Date: Oct. 15, 2026

(54) PREDICTION SYSTEM AND PREDICTION METHOD OF TRANSFORMER LOAD

(71) Applicant: Fortune Electric Co., Ltd., Taoyuan City (TW)

(72) Inventors: CHIA-CHING LIN, Taoyuan City (TW); CHIA-TAI HSU, Taoyuan City (TW); CHAN-EN PEN, Taoyuan City (TW)

(21) Appl. No.: 19/271,746

(22) Filed: Jul. 16, 2025

(30) Foreign Application Priority Data
Apr. 15, 2025 (TW) 114114116

(51) Int. Cl. H02J 3/00; H02J 13/00; H05K 7/20

(52) U.S. Cl. CPC H02J 3/003; H02J 13/12; H02J 13/16; H05K 7/20136; H05K 7/20209; H02J 2103/30

(57) ABSTRACT

A prediction system and a prediction method of a transformer load. The prediction system includes a smart transformer IoT system, a remote terminal unit connected to the smart transformer IoT system, and at least one transformer. The smart transformer IoT system obtains transformer load data of the transformer within a specified future period of time via the remote terminal unit. When a load factor of the transformer load data reaches a first alarm value, a first alarm is output, and an operation power of a cooling system is pre-activated according to the first alarm. When the load factor reaches a second alarm value, a second alarm is output to a maintenance terminal. The prediction system can pre-activate the cooling system or alert the maintenance terminal according to different alarms, so that the risk of damaging the transformer is decreased.

### CROSS-REFERENCE TO RELATED PATENT APPLICATION

This application claims the benefit of priority to Taiwan Patent Application No. 114114116, filed on Apr. 15, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a prediction system, and more particularly to a prediction system and a prediction method of a transformer load.

### BACKGROUND OF THE DISCLOSURE

A transformer is an important apparatus in an electric power system for conversion and communication of electric power. In order for the electric power to be transmitted from a power plant to end-users, the electric power needs to pass through various step-up or step-down transformers. However, fire or explosions may occur due to malfunction or damage of the transformer, thereby leading to public safety issues.

Currently, the transformer plays an important role in the electric power system. When the transformer is in operation, a high temperature is generated, which causes a service life of the transformer to be decreased. The main reason for generation of the high temperature is a load of the transformer. However, the existing electric power system is not capable of predicting the load in real time, predicting future load requirements of the transformer through machine learning, reducing occurrence of overheating of the transformer, providing complete information (e.g., prediction of the service life) of the transformer to a user, or providing countermeasures against future overheating of the transformer. Therefore, how to maintain stability of the transformer and activate a cooling system before the transformer is overheated has become one of the important issues to be addressed in the relevant industry.

### SUMMARY OF THE DISCLOSURE

In response to the above-referenced technical inadequacies, the present disclosure provides a prediction system and a prediction method of a transformer load, so as to effectively predict various states of the transformer load within a specified future period of time, enable a user to predict future load requirements of a transformer through machine learning, and reduce occurrence of overheating of the transformer.

In order to solve the above-mentioned problems, one of the technical aspects adopted by the present disclosure is to provide a prediction system of a transformer load. The prediction system includes a smart transformer IoT system, a remote terminal unit, and at least one transformer. The remote terminal unit is communicatively connected to the smart transformer IoT system. The at least one transformer is electrically connected to the remote terminal unit. The smart transformer IoT system obtains one or multiple pieces of transformer load data of the transformer within a specified future period of time via the remote terminal unit. The smart transformer IoT system performs data cleaning on the transformer load data. The smart transformer IoT system performs data normalization on the cleaned transformer load data. The smart transformer IoT system performs feature screening on the normalized transformer load data. The smart transformer IoT system uses the screened transformer load data to establish at least one transformer load prediction model at different learning time intervals. According to the at least one transformer load prediction model, the smart transformer IoT system uses the screened transformer load data to generate one or multiple pieces of root mean square error data. According to the root mean square error data, the smart transformer IoT system determines the at least one transformer load prediction model to be a bidirectional gated recurrent unit model. When a load factor of the transformer load data within the specified future period of time reaches a first alarm value, the smart transformer IoT system outputs a first alarm via the bidirectional gated recurrent unit model, and pre-activates an operation power of a cooling system according to the first alarm. When the load factor of the transformer load data within the specified future period of time reaches a second alarm value, the smart transformer IoT system outputs a second alarm to at least one maintenance terminal via the bidirectional gated recurrent unit model.

In one of the possible or preferred embodiments, the smart transformer IoT system performs hyperparameter optimization on the bidirectional gated recurrent unit model.

In one of the possible or preferred embodiments, the smart transformer IoT system obtains the one or multiple pieces of the transformer load data of the at least one transformer for next four hours or seven days via the remote terminal unit.

In one of the possible or preferred embodiments, the smart transformer IoT system re-samples the transformer load data for time interval unification, the smart transformer IoT system deletes null values in the transformer load data by adding a transformer serial number and a voltage factor, and the smart transformer IoT system selects an adaptation factor of the transformer load data.

In one of the possible or preferred embodiments, the smart transformer IoT system performs min-max normalization to scale the transformer load data within a range of between 0 and 1.

In one of the possible or preferred embodiments, the smart transformer IoT system performs the feature screening on the load factor, an ambient temperature factor, a year factor, a season factor, a month factor, a weekend factor, and a national holiday factor of the transformer load data, and on a voltage factor and a current factor of a monitoring apparatus.

In one of the possible or preferred embodiments, the smart transformer IoT system uses the screened transformer load data to establish the at least one transformer load prediction model at the learning time interval of four hours, eight hours, or twelve hours.

In one of the possible or preferred embodiments, the smart transformer IoT system establishes the at least one transformer load prediction model according to historical data of a specified transformer or a transformer having a background similarity with the specified transformer above a threshold value.

In one of the possible or preferred embodiments, the at least one transformer load prediction model includes a gated recurrent unit model, a long short-term memory model, and the bidirectional gated recurrent unit model.

In one of the possible or preferred embodiments, when the load factor of the transformer load data does not reach the first alarm value, the operation power of the cooling system is decreased to zero at a specified speed.

In order to solve the above-mentioned problems, another one of the technical aspects adopted by the present disclosure is to provide a prediction method of a transformer load. The prediction method includes: configuring a smart transformer IoT system to obtain one or multiple pieces of transformer load data within a specified future period of time via a remote terminal unit; performing data cleaning on the transformer load data; performing data normalization on the cleaned transformer load data; performing feature screening on the normalized transformer load data; using the screened transformer load data to establish at least one transformer load prediction model at different learning time intervals; using the screened transformer load data to generate one or multiple pieces of root mean square error data according to the at least one transformer load prediction model; determining the at least one transformer load prediction model to be a bidirectional gated recurrent unit model according to the root mean square error data; configuring the smart transformer IoT system to output a first alarm via the bidirectional gated recurrent unit model when a load factor of the transformer load data within the specified future period of time reaches a first alarm value, and pre-activating an operation power of a cooling system according to the first alarm; and configuring the smart transformer IoT system to output a second alarm to at least one maintenance terminal via the bidirectional gated recurrent unit model when the load factor of the transformer load data within the specified future period of time reaches a second alarm value.

In one of the possible or preferred embodiments, after the process of determining the at least one transformer load prediction model to be the bidirectional gated recurrent unit model according to the root mean square error data, the prediction method further includes: performing hyperparameter optimization on the bidirectional gated recurrent unit model.

In one of the possible or preferred embodiments, in the process of configuring the smart transformer IoT system to obtain the one or multiple pieces of the transformer load data within the specified future period of time via the remote terminal unit, the prediction method further includes: obtaining, by the smart transformer IoT system, the one or multiple pieces of the transformer load data for next four hours or seven days via the remote terminal unit.

In one of the possible or preferred embodiments, in the process of performing the data cleaning on the transformer load data, the data cleaning includes: re-sampling the transformer load data for time interval unification; deleting null values in the transformer load data by adding a transformer serial number and a voltage factor; and selecting an adaptation factor of the transformer load data.

In one of the possible or preferred embodiments, in the process of performing the data normalization on the cleaned transformer load data, the data normalization includes: performing min-max normalization to scale the transformer load data within a range of between 0 and 1.

In one of the possible or preferred embodiments, in the process of performing the feature screening on the normalized transformer load data, the prediction method includes: performing the feature screening on the load factor, an ambient temperature factor, a year factor, a season factor, a month factor, a weekend factor, and a national holiday factor of the transformer load data, and on a voltage factor and a current factor of a monitoring apparatus.

In one of the possible or preferred embodiments, in the process of using the screened transformer load data to establish the at least one transformer load prediction model at the different learning time intervals, the prediction method includes: using the screened transformer load data to establish the at least one transformer load prediction model at the learning time interval of four hours, eight hours, or twelve hours.

In one of the possible or preferred embodiments, in the process of using the screened transformer load data to establish the at least one transformer load prediction model at the different learning time intervals, the prediction method includes: establishing the at least one transformer load prediction model according to historical data of a specified transformer or a transformer having a background similarity with the specified transformer above a threshold value.

In one of the possible or preferred embodiments, in the process of using the screened transformer load data to establish the at least one transformer load prediction model at the different learning time intervals, the prediction method includes: configuring the at least one transformer load prediction model to include a gated recurrent unit model, a long short-term memory model, and the bidirectional gated recurrent unit model.

In one of the possible or preferred embodiments, in the process of configuring the smart transformer IoT system to output the first alarm via the bidirectional gated recurrent unit model when the load factor of the transformer load data within the specified future period of time reaches the first alarm value, and pre-activating the operation power of the cooling system according to the first alarm, the prediction method includes: decreasing, when the load factor of the transformer load data does not reach the first alarm value, the operation power of the cooling system to zero at a specified speed.

Therefore, in the prediction system and the prediction method of the transformer load provided by the present disclosure, data pre-processing performed by the smart transformer IoT system includes the data cleaning, the data normalization, and the feature screening, which enable the transformer load data to be better adapted for training the bidirectional gated recurrent unit model and enhance efficacy and accuracy of the bidirectional gated recurrent unit model. In the present disclosure, according to the alarm values, different alarms are output for pre-activating the cooling system or alerting personnel of the maintenance terminal to inspect the state of the transformer load on site, so as to effectively reduce the risk of damaging the transformer. Furthermore, the bidirectional gated recurrent unit model having a minimum error in the at least one transformer load prediction model can be determined according to the root mean square error data, so as to effectively increase the accuracy.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a block diagram of a prediction system of a transformer load according to the present disclosure;

FIG. 2 is another block diagram of the prediction system of the transformer load according to the present disclosure; and

FIG. 3 is a method flowchart of a prediction method of the transformer load according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

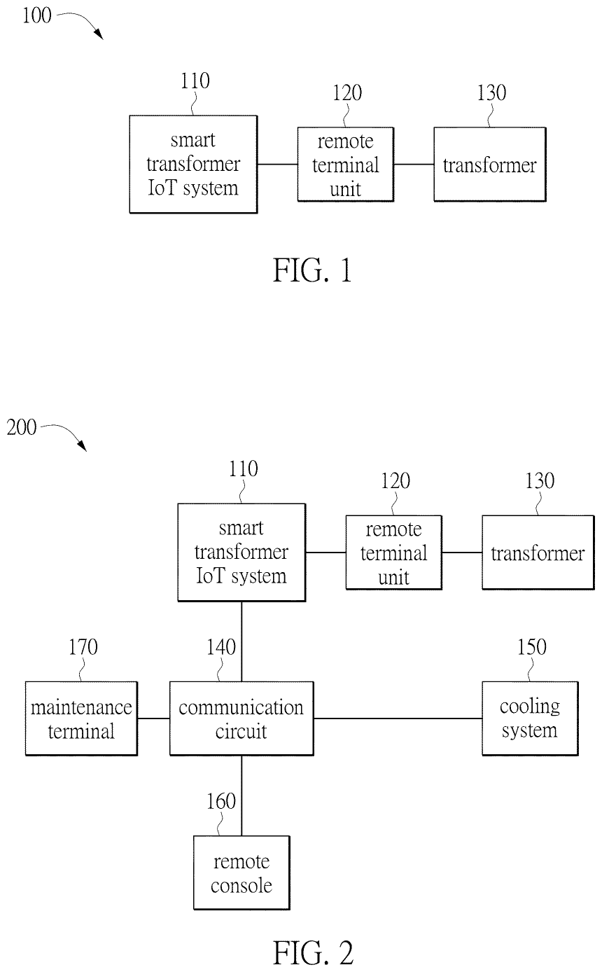

Referring to FIG. 1 and FIG. 2, one embodiment of the present disclosure provides a prediction system of a transformer load. A prediction system 100 includes a smart transformer IT system (SIOT) 110, a remote terminal unit (RTU) 120, and at least one transformer 130. The remote terminal unit 120 is communicatively connected to the smart transformer IoT system 110. The transformer 130 is electrically connected to the remote terminal unit 120. The smart transformer IoT system 110 obtains one or multiple pieces of transformer load data of the transformer 130 within a specified future period of time via the remote terminal unit 120. The smart transformer IoT system 110 has five main functions, and provides a manufacturing progress, a maintenance system, a smart diagnosis system, and a real-time monitoring system. The smart transformer IoT system 110 can be stored in a processing unit of a microcontroller or other general-purpose or special-purpose processors. The remote terminal unit 120 is a modular remote terminal solution for application in the field of transformers associated with electrical grids, and can assist in continuously processing and providing states and event time information. In one embodiment, the remote terminal unit 120 can monitor the state of the transformer load in real time, so as to prevent the risk of damage caused by overheating of the transformer load. The remote terminal unit 120 is usually disposed in the transformer 130 or on a side outside of the transformer 130. For example, the smart transformer IoT system 110 obtains the one or multiple pieces of the transformer load data for next four hours or seven days via the remote terminal unit 120. In a situation where the transformer load within the next four hours or seven days may be overloaded, a smart mode is turned on for pre-activating a cooling system 150 (e.g., a fan) to effectively cool down the transformer load. In this way, the risk of damaging a transformer can be reduced.

In one embodiment, the smart transformer IoT system 110 performs data cleaning on the transformer load data. The data cleaning includes: configuring the smart transformer IoT system 110 to re-sample the transformer load data for time interval unification; configuring the smart transformer IoT system 110 to delete null values in the transformer load data by adding a transformer serial number and a voltage factor; and configuring the smart transformer IoT system 110 to select an adaptation factor of the transformer load data. In the process of re-sampling the transformer load data for time interval unification, when the remote terminal unit 120 performs data sampling at inconsistent time intervals, the time intervals for sampling the transformer load data are modified to be consistent (such as five minutes, ten minutes, or twenty minutes). When the null values are present in the original transformer load data, the null values are deleted by adding the transformer serial number and the voltage factor at specified sampling time points, so as to maintain integrity of the transformer load data. The smart transformer IoT system 110 selects the adaptation factor of the transformer load data. For example, the adaptation factor includes the transformer serial number, the voltage factor, a current factor, a load factor, an ambient temperature factor, a year factor, a season factor, a month factor, a weekend factor, and a week factor. Under a high temperature environment, the ambient temperature factor may cause overheating of the transformer load. Conversely, under a low temperature environment, the ambient temperature factor is less likely to cause overheating of the temperature load. A possible influence of the year factor resides in that power consumption of the manufacturing industry is generally high when a certain year exhibits strong economic performance. A possible influence of the season factor resides in that an overall amount of the power consumption is adjusted by a vendor in response to increased or decreased orders for a certain quarter. For the weekend factor, industrial power consumption is usually lower during weekends and higher during non-weekends. The concept of the week factor is similar to the weekend factor, and will not be reiterated herein. In other words, processing of missing values and outliers and processing of duplicates are performed in the data cleaning step, so that more complete and accurate data can be obtained.

In one embodiment, the smart transformer IoT system 110 performs data normalization on the cleaned transformer load data. For example, the purpose of data standardization is to restrict a data range without influencing distribution of the original transformer load data. The standardization is applied to machine learning, and comparison can be made after converting data from different units into the same unit. The data normalization is to scale the transformer load data within a range of between 0 and 1 by min-max normalization, so that deviations in the transformer load data can be effectively reduced. In other words, the data normalization enables data of different ranges to be unified into one standard range, thereby achieving deviation reduction in the data.

In one embodiment, the smart transformer IoT system 110 performs feature screening on the normalized transformer load data. Specifically, the smart transformer IoT system 110 performs the feature screening on the load factor, the ambient temperature factor, the year factor, the season factor, the month factor, the weekend factor, and a national holiday factor of the transformer load data, and on the voltage factor and the current factor of a monitoring apparatus. Correlation analysis is performed on factors that are likely to influence a load, and the weekend factor and the national holiday factor are days on which the industrial power consumption is lower. The voltage factor and the current factor of the monitoring apparatus influence electric power. For example, the higher the transformer load, the higher the electric power of the monitoring apparatus. The lower the transformer load, the lower the electric power of the monitoring apparatus. In other words, the feature screening is to select a feature factor with high correlation. Since a certain relationship often exists between a transformer and the feature factor with high correlation, said feature factor can be used to predict a target variable of the transformer load.

In one embodiment, the smart transformer IoT system 110 uses the screened transformer load data to establish at least one transformer load prediction model at different learning time intervals. By using the transformer load data that is subjected to the feature screening, the smart transformer IoT system 110 establishes the at least one transformer load prediction model at the learning time interval of four hours, eight hours, or twelve hours. The at least one transformer load prediction model includes a gated recurrent unit (GRU) model, a long short-term memory (LSTM) model, and a bidirectional gated recurrent unit (Bi-GRU) model.

In one embodiment, according to the at least one transformer load prediction model, the smart transformer IoT system 110 uses the screened transformer load data to generate one or multiple pieces of root mean square error (RMSE) data. The root mean square error data is one of many metrics to evaluate whether a model is good or bad. In addition, the unit of the root mean square error data is consistent with the unit of a prediction target, so that the root mean square error data is selected as the metric for evaluating various models.

In one embodiment, according to the root mean square error data, the smart transformer IoT system 110 determines the at least one transformer load prediction model to be the bidirectional gated recurrent unit model. As for selecting the bidirectional gated recurrent unit model out of the gated recurrent unit model, the long short-term memory model, and the bidirectional gated recurrent unit model to simulate changes of the transformer load data, reference can be made to the following table illustrating relationships between the models and the root mean square error data.

Table illustrating relationships between models and root mean square error data

| | Length | | Root | | Length | | Root |
|---|---|---|---|---|---|---|---|
| | of | | mean | | of | | mean |
| Adopted | learning | | square | Adopted | learning | | square |
| factor | time | Model | error | factor | time | Model | error |
| Load factor | 4 hours | LSTM | 4.9053% | Load factor | 12 hours | LSTM | 7.8971% |
| | | model | | and | | model | |
| | | GRU | 4.6320% | ambient | | GRU | 7.0156% |
| | | model | | temperature | | model | |
| | | | | factor | | | |
| | | Bi- | 3.8499% | Load | 4 hours | LSTM | 4.2934% |
| | | GRU | | factor, | | model | |
| | | model | | ambient | | | |
| Load factor | 4 hours | LSTM | 4.3119% | temperature | | GRU | 4.0717% |
| and | | model | | factor, year | | model | |
| ambient | | GRU | 4.4933% | factor, | | Bi-GRU | 2.8813% |
| temperature | | model | | season | | model | |
| factor | | Bi- | 3.2011% | factor, and | 8 hours | LSTM | 6.1021% |
| | | GRU | | weekend | | model | |
| | | model | | factor | | | |
| | 8 hours | LSTM | 6.6310% | | | GRU | 5.5846% |
| | | model | | | | model | |
| | | GRU | 5.6607% | | | Bi-GRU | 3.2932% |
| | | model | | | | model | |
| | | Bi- | 4.0027% | | | | |
| | | GRU | | | | | |
| | | model | | | | | |

From the above-mentioned table illustrating the relationships between the models and the root mean square error data, it can be observed that the model is more accurate when the load factor, the ambient temperature factor, the year factor, the month factor, the season factor, or the weekend factor is used as an input variable. In all situations, the root mean square error data of the bidirectional gated recurrent unit model is lower than that of the long short-term memory model or the gated recurrent unit model. Hence, according to the root mean square error data, the smart transformer IoT system 110 determines the at least one transformer load prediction model to be the bidirectional gated recurrent unit model. Moreover, the smart transformer IoT system 110 establishes the at least one transformer load prediction model according to historical data of a specified transformer or a transformer having a background similarity with the specified transformer above a threshold value (e.g., 80%).

In one embodiment, when a transformer that is to be subjected to a load prediction has collected data for more than six months, training and learning of the bidirectional gated recurrent unit model will be carried out by use of the historical data of the above-mentioned factors in said transformer. If said transformer is new, a model having a background similarity with said transformer (e.g., a parameter similarity of above 80%) will be used. For example, new data will also be transmitted to the bidirectional gated recurrent unit model for re-training within time intervals of each day, each week, each month, and each season, so as to ensure that the bidirectional gated recurrent unit model has an up-to-date transformer load mode. That is to say, since the new transformer has no historical records, one bidirectional gated recurrent unit model having a background similarity with the new transformer will firstly be used, and the new data will be timely transmitted to the bidirectional gated recurrent unit model for training, so as to replace the original bidirectional gated recurrent unit model. After a new bidirectional gated recurrent unit model is completed, a prediction program begins to predict the transformer load, and calculates an error value (e.g., a root mean square error). If the error value is too large, the structure of the bidirectional gated recurrent unit model will be adjusted for effectively increasing real-time updateability of a model structure.

In one embodiment, the smart transformer IoT system 110 performs hyperparameter optimization on the bidirectional gated recurrent unit model. Specifically, a hyperparameter can greatly influence model performance, and different hyperparameter configurations influence a training speed, accuracy, and a generalization ability of the bidirectional gated recurrent unit model. As such, hyperparameter tuning is a very important part of a training process of a deep learning model. For the bidirectional gated recurrent unit model, the hyperparameter tuning includes, for example, tweaking the number of Bi-GRU neurons from a first layer to a fourth layer, the number of neurons in a dense (fully connected) layer, a learning rate, an activation function in the dense layer, regularization techniques (dropout), an optimizer, an instruction cycle (epochs), and a batch size. Furthermore, an original input variable is added with a future time-related message (e.g., the year factor, the season factor, the month factor, and the weekend factor) to act as an optimized input variable, so as to enhance adaptability of the bidirectional gated recurrent unit model to unknown data, prevent overfitting of the model on learning data, and assist the bidirectional gated recurrent unit model in better learning correlations between variable factors of the transformer load data. In the present embodiment, the smart transformer IoT system 110 adopts the hyperparameter-optimized bidirectional gated recurrent unit model, and the root mean square error data is already below the standard (1.7%) when learning time is four hours or eight hours (as shown in the following table illustrating relationships between the learning time and the root mean square error).

Table illustrating relationships between learning time and root mean square error

| | | | Trans- | Root | | Trans- | Root |
|---|---|---|---|---|---|---|---|
| | | | former | mean | | former | mean |
| | Adopted | Learning | serial | square | Learning | serial | square |
| Model | factor | time | number | error | time | number | error |
| Bi- | Load | 4 hours | 08020 | 1.3724% | 8 hours | 08020 | 1.3166% |
| GRU | factor, | | DR1120001 | 0.9579% | | DR1120001 | 0.9189% |
| model | ambient | | DR1120002 | 0.4966% | | DR1120002 | 0.4764% |
| | temper- | | | | | | |
| | ature | | | | | | |
| | factor, | | | | | | |
| | year | | | | | | |
| | factor, | | | | | | |
| | season | | | | | | |
| | factor, | | | | | | |
| | and | | | | | | |
| | week- | | | | | | |
| | end | | | | | | |
| | factor | | | | | | |

In one embodiment, as compared with FIG. 1, a prediction system 200 shown in FIG. 2 further includes a communication circuit 140, the cooling system 150, a remote console 160, and a maintenance terminal 170. When the load factor of the transformer load data within the specified future period of time reaches a first alarm value, the smart transformer IoT system 110 outputs a first alarm to the cooling system 150 via the bidirectional gated recurrent unit model and the communication circuit 140, and pre-activates an operation power of the cooling system 150 according to the first alarm, so as to decrease a temperature of the transformer 130. For example, when the load factor of the transformer load data reaches the first alarm value within the next four hours or seven days, the smart transformer IT system 110 outputs the first alarm to the remote console 160 (e.g., a remote server) via the bidirectional gated recurrent unit model and the communication circuit 140. In order to increase flexibility and immediacy, the first alarm can be an indication light changing from a green color to a yellow color, and can also be emission of a gentle audio reminder. In one embodiment, when the load factor of the transformer load data does not reach the first alarm value, the operation power of the cooling system 150 is decreased to zero at a specified speed. Specifically, when the load factor does not reach the first alarm value, the operation power of the cooling system 150 is slowly decreased to zero according to the load factor of the transformer load data, so as to save energy consumption of the cooling system 150. That is to say, the cooling system 150 (e.g., a fan) can immediately and automatically start or stop operation at a specified future time, and can be adjusted to operate at a predetermined operation level. The predetermined operation level is relatively adjusted according to the size of the transformer load, so as to effectively prevent a transformer from being overheated and damaged.

In one embodiment, when the load factor of the transformer load data within the specified future period of time reaches a second alarm value, the smart transformer IoT system 110 outputs a second alarm to one or multiple ones of the maintenance terminal 170 via the bidirectional gated recurrent unit model and the communication circuit 140. For example, the second alarm is output to the maintenance terminal 170 for notifying a worker to remove abnormalities on site. That is, since using the first alarm to activate the cooling system 150 may not be sufficient enough to eliminate overheating of the transformer load, the second alarm is used to indicate that the transformer 130 is heated to an extent as to urgently require a maintenance person to eliminate overheating of the transformer load on site. The second alarm can be the indication light changing from the green color to a red color, and can also be emission of a loud and more rapid audio reminder, both of which indicate urgency of overheating.

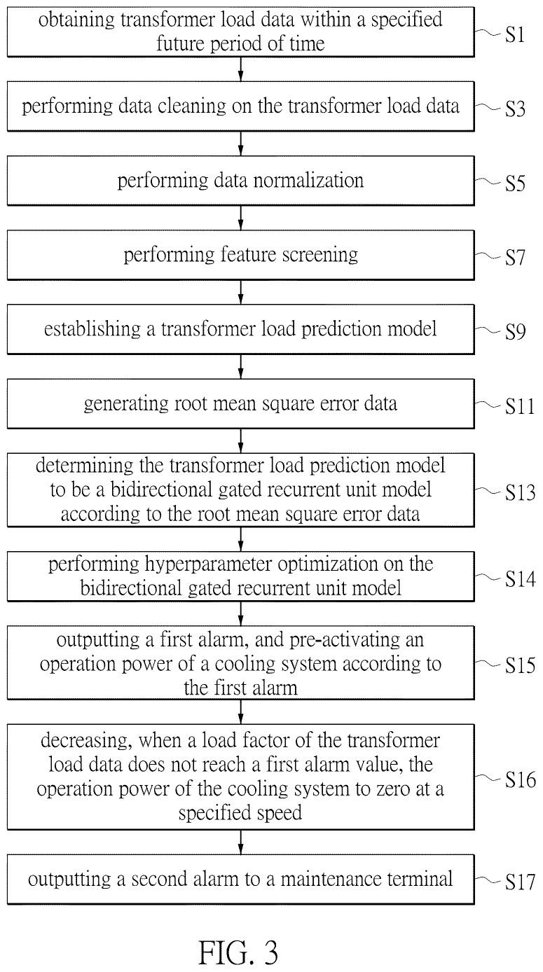

Referring to FIG. 3, the present disclosure provides a prediction method of a transformer load, which can be implemented by the prediction system of the transformer load provided in the embodiments of FIG. 1 and FIG. 2. The prediction method includes: configuring a smart transformer IoT system to obtain one or multiple pieces of transformer load data within a specified future period of time via a remote terminal unit (S1); performing data cleaning on the transformer load data (S3); performing data normalization on the cleaned transformer load data (S5); performing feature screening on the normalized transformer load data (S7); using the screened transformer load data to establish at least one transformer load prediction model at different learning time intervals (S9); using the screened transformer load data to generate one or multiple pieces of root mean square error data according to the at least one transformer load prediction model (S11); determining the at least one transformer load prediction model to be a bidirectional gated recurrent unit model according to the one or multiple pieces of the root mean square error data (S13); performing hyperparameter optimization on the bidirectional gated recurrent unit model (S14); configuring the smart transformer IoT system to output a first alarm via the bidirectional gated recurrent unit model when a load factor of the transformer load data within the specified future period of time reaches a first alarm value, and pre-activating an operation power of a cooling system according to the first alarm (S15); decreasing, when the load factor of the transformer load data does not reach the first alarm value, the operation power of the cooling system to zero at a specified speed (S16); and configuring the smart transformer IoT system to output a second alarm to at least one maintenance terminal via the bidirectional gated recurrent unit model when the load factor of the transformer load data within the specified future period of time reaches a second alarm value (S17).

The related technical details mentioned in the descriptions of the embodiments of FIG. 1 and FIG. 2 are still valid in the embodiment of FIG. 3, and will not be reiterated herein for the sake of brevity. Similarly, the related technical details mentioned in the embodiment of FIG. 3 can also be applied to the embodiments of FIG. 1 and FIG. 2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A prediction system of a transformer load, comprising:
a smart transformer IoT system;
a remote terminal unit communicatively connected to the smart transformer IoT system; and
at least one transformer electrically connected to the remote terminal unit, wherein the smart transformer IoT system obtains one or multiple pieces of transformer load data of the at least one transformer within a specified future period of time via the remote terminal unit;
wherein the smart transformer IoT system performs data cleaning on the transformer load data;
wherein the smart transformer IoT system performs data normalization on the transformer load data that is cleaned;
wherein the smart transformer IoT system performs feature screening on the transformer load data that is normalized;
wherein the smart transformer IoT system uses the transformer load data that is screened to establish at least one transformer load prediction model at different learning time intervals;
wherein, according to the at least one transformer load prediction model, the smart transformer IoT system uses the transformer load data that is screened to generate one or multiple pieces of root mean square error data;
wherein, according to the one or multiple pieces of the root mean square error data, the smart transformer IoT system determines the at least one transformer load prediction model to be a bidirectional gated recurrent unit model;
wherein, when a load factor of the transformer load data within the specified future period of time reaches a first alarm value, the smart transformer IoT system outputs a first alarm via the bidirectional gated recurrent unit model, and pre-activates an operation power of a cooling system according to the first alarm; and
wherein, when the load factor of the transformer load data within the specified future period of time reaches a second alarm value, the smart transformer IoT system outputs a second alarm to at least one maintenance terminal via the bidirectional gated recurrent unit model.

2. The prediction system according to claim 1, wherein the smart transformer IoT system performs hyperparameter optimization on the bidirectional gated recurrent unit model.

3. The prediction system according to claim 1, wherein the smart transformer IoT system obtains the one or multiple pieces of the transformer load data of the at least one transformer for next four hours or seven days via the remote terminal unit.

4. The prediction system according to claim 1, wherein the smart transformer IoT system re-samples the transformer load data for time interval unification, the smart transformer IoT system deletes null values in the transformer load data by adding a transformer serial number and a voltage factor, and the smart transformer IoT system selects an adaptation factor of the transformer load data.

5. The prediction system according to claim 1, wherein the smart transformer IoT system performs min-max normalization to scale the transformer load data within a range of between 0 and 1.

6. The prediction system according to claim 1, wherein the smart transformer IoT system performs the feature screening on the load factor, an ambient temperature factor, a year factor, a season factor, a month factor, a weekend factor, and a national holiday factor of the transformer load data, and on a voltage factor and a current factor of a monitoring apparatus.

7. The prediction system according to claim 1, wherein the smart transformer IoT system uses the transformer load data that is screened to establish the at least one transformer load prediction model at the learning time interval of four hours, eight hours, or twelve hours.

8. The prediction system according to claim 1, wherein the smart transformer IoT system establishes the at least one transformer load prediction model according to historical data of a specified transformer or a transformer having a background similarity with the specified transformer above a threshold value.

9. The prediction system according to claim 1, wherein the at least one transformer load prediction model includes a gated recurrent unit model, a long short-term memory model, and the bidirectional gated recurrent unit model.

10. The prediction system according to claim 1, wherein, when the load factor of the transformer load data does not reach the first alarm value, the operation power of the cooling system is decreased to zero at a specified speed.

11. A prediction method of a transformer load, comprising:
configuring a smart transformer IoT system to obtain one or multiple pieces of transformer load data within a specified future period of time via a remote terminal unit;
performing data cleaning on the transformer load data;
performing data normalization on the transformer load data that is cleaned;
performing feature screening on the transformer load data that is normalized;
using the transformer load data that is screened to establish at least one transformer load prediction model at different learning time intervals;
using the transformer load data that is screened to generate one or multiple pieces of root mean square error data according to the at least one transformer load prediction model;
determining the at least one transformer load prediction model to be a bidirectional gated recurrent unit model according to the one or multiple pieces of the root mean square error data;
configuring the smart transformer IoT system to output a first alarm via the bidirectional gated recurrent unit model when a load factor of the transformer load data within the specified future period of time reaches a first alarm value, and pre-activating an operation power of a cooling system according to the first alarm; and
configuring the smart transformer IoT system to output a second alarm to at least one maintenance terminal via the bidirectional gated recurrent unit model when the load factor of the transformer load data within the specified future period of time reaches a second alarm value.

12. The prediction method according to claim 11, wherein, after the process of determining the at least one transformer load prediction model to be the bidirectional gated recurrent unit model according to the one or multiple pieces of the root mean square error data, the prediction method further includes:
performing hyperparameter optimization on the bidirectional gated recurrent unit model.

13. The prediction method according to claim 11, wherein, in the process of configuring the smart transformer IoT system to obtain the one or multiple pieces of the transformer load data within the specified future period of time via the remote terminal unit, the prediction method further includes:
obtaining, by the smart transformer IoT system, the one or multiple pieces of the transformer load data for next four hours or seven days via the remote terminal unit.

14. The prediction method according to claim 11, wherein, in the process of performing the data cleaning on the transformer load data, the data cleaning includes:
re-sampling the transformer load data for time interval unification;
deleting null values in the transformer load data by adding a transformer serial number and a voltage factor; and
selecting an adaptation factor of the transformer load data.

15. The prediction method according to claim 11, wherein, in the process of performing the data normalization on the transformer load data that is cleaned, the data normalization includes:
performing min-max normalization to scale the transformer load data within a range of between 0 and 1.

16. The prediction method according to claim 11, wherein, in the process of performing the feature screening on the transformer load data that is normalized, the prediction method includes:
performing the feature screening on the load factor, an ambient temperature factor, a year factor, a season factor, a month factor, a weekend factor, and a national holiday factor of the transformer load data, and on a voltage factor and a current factor of a monitoring apparatus.

17. The prediction method according to claim 11, wherein, in the process of using the transformer load data that is screened to establish the at least one transformer load prediction model at the different learning time intervals, the prediction method includes:
using the transformer load data that is screened to establish the at least one transformer load prediction model at the learning time interval of four hours, eight hours, or twelve hours.

18. The prediction method according to claim 11, wherein, in the process of using the transformer load data that is screened to establish the at least one transformer load prediction model at the different learning time intervals, the prediction method includes:
establishing the at least one transformer load prediction model according to historical data of a specified transformer or a transformer having a background similarity with the specified transformer above a threshold value.

19. The prediction method according to claim 11, wherein, in the process of using the transformer load data that is screened to establish the at least one transformer load prediction model at the different learning time intervals, the prediction method includes:
configuring the at least one transformer load prediction model to include a gated recurrent unit model, a long short-term memory model, and the bidirectional gated recurrent unit model.

20. The prediction method according to claim 11, wherein, in the process of configuring the smart transformer IoT system to output the first alarm via the bidirectional gated recurrent unit model when the load factor of the transformer load data within the specified future period of time reaches the first alarm value, and pre-activating the operation power of the cooling system according to the first alarm, the prediction method includes:
decreasing, when the load factor of the transformer load data does not reach the first alarm value, the operation power of the cooling system to zero at a specified speed.
